(19) United States
(12) Patent Application Publication
(10) Pub. No.: US 2018/0294211 A1
(43) Pub. Date: Oct. 11, 2018

(54) VERTICALLY CURVED MECHANICALLY FLEXIBLE INTERCONNECTS, METHODS OF MAKING THE SAME, AND METHODS OF USE

(71) Applicant: Georgia Tech Research Corporation, Atlanta, GA (US)

(72) Inventors: MUHANNAD S. BAKIR, ATLANTA, GA (US); HYUNG SUK YANG, ATLANTA, GA (US); CHAOQI ZHANG, ATLANTA, GA (US)

(21) Appl. No.: 15/570,918

(22) PCT Filed: Apr. 28, 2016
(86) PCT No.: PCT/US16/29799

§ 371 Date: Oct. 31, 2017

Related U.S. Application Data
(60) Provisional application No. 62/155,960, filed on May 1, 2015.
(60) Provisional application No. 62/255,935, filed on Nov. 16, 2015.
(60) Provisional application No. 62/306,307, filed on Mar. 10, 2016.

(51) Int. Cl. H01L 23/498; H01L 23/538; H01L 25/065; H01L 23/00; H01L 21/48; G01R 1/067; G01R 1/073

(52) U.S. Cl. CPC H01L 23/49811; H01L 2224/1703; H01L 23/5386; H01L 25/0652; H01L 24/67; H01L 24/69; H01L 24/70; H01L 24/17; H01L 24/16; H01L 21/4853; G01R 1/06722; G01R 1/0735; G01R 1/07378; H01L 2225/06596; H01L 2224/16145; H01L 2224/16225; H01L 23/49838

(57) ABSTRACT

Disclosed are various embodiments that involve mechanically flexible interconnects, methods of making mechanically flexible interconnects, methods of using mechanically flexible interconnects, and the like.

### CLAIM OF PRIORITY TO RELATED APPLICATION

This application claims priority to the following copending U.S. provisional applications: provisional application entitled, “Single and Dual-Sided Substrates with Flexible Interconnects of Differing Sizes,” having Ser. No. 62/155,960, filed May 1, 2015; provisional application entitled, “Mechanical Interconnects,” having Ser. No. 62/255,935, filed Nov. 16, 2015; and provisional application entitled, “Mechanically Flexible Interconnects for Large Scale Heterogeneous System Integration,” having Ser. No. 62/306,307, filed Mar. 10, 2016. Each of the above applications are entirely incorporated herein by reference.

### BACKGROUND

Stacking wafers, dies or chips, and the formation of multi-die package with dense interconnection are methods to provide increased density in an electronic system. Such three-dimensional (3D) integrated circuits and dense package interconnections can include chips manufactured via different technologies or processes, without the need to modify the manufacturing process used for each chip. Thermal and physical stresses can result at the connection points between chips in a 3D integrated circuit or dense multi-die packages. As a result, the interface used between such chips is essential to its operation. Probing and testing interfaces, which may be temporary connected to a chip or an integrated circuit, can also be subject to stresses at the connection points. Each chip in the 3D integrated circuit can also have irregularities in shape, making interconnection problematic. Specialization of interconnects can help to alleviate these issues.

### SUMMARY

Disclosed are various embodiments that involve mechanically flexible interconnects, methods of making mechanically flexible interconnects, methods of using mechanically flexible interconnects, and the like.

One embodiment includes a substrate, among others, having: a first mechanically flexible interconnect having a first thickness and a second mechanically flexible interconnect having a second thickness. The first thickness and the second thickness are different. The first mechanically flexible interconnect and the second mechanically flexible interconnect have a substantially equivalent compliance.

Another embodiment includes a substrate, among others, having: a first mechanically flexible interconnect comprised of at least one first material and a second mechanically flexible interconnect comprised of at least one second material. At least one of the first material and at least one of the second material are different. The first mechanically flexible interconnect and the second mechanically flexible interconnect have a substantially equivalent compliance.

Yet another embodiment includes a bridge chip for connecting a plurality of chips, the bridge chip being configured to connect a first side of the bridge chip to a first chip via a first plurality of bumps. The bridge chip also connects the first side of the bridge chip to a second chip via a second plurality of bumps. The bridge chip also connects a second side of the bridge chip to a substrate, wherein the first chip is connected to the substrate via a first mechanically flexible interconnect, the second chip is connected to the substrate via a second mechanically flexible interconnect, and wherein the first mechanically flexible interconnect and the second mechanically flexible interconnect have a similar compliance.

A further embodiment includes a method, among others, including: moving a testing interface into a testing position, wherein the testing interface comprises a first mechanically flexible interconnect and a second mechanically flexible interconnect, each of the first mechanically flexible interconnect and the second mechanically flexible interconnect having a similar compliance. The method also comprises contacting the first mechanically flexible interface with a first portion of a circuit. The method also comprises contacting the second mechanically flexible interface with a second portion of the circuit. The method also comprises testing the first portion of the circuit and the second portion of the circuit.

### BRIEF DESCRIPTION OF THE DRAWINGS

Many aspects of the present disclosure can be better understood with reference to the following drawings. The components in the drawings are not necessarily to scale, with emphasis instead being placed upon clearly illustrating the principles of the disclosure. Moreover, in the drawings, like reference numerals designate corresponding parts throughout the several views.

FIGS. 1A-1C illustrate cross-sectional views of mechanically flexible interconnects according to representational embodiments.

FIGS. 2A and 2B illustrate cross-sectional views of mechanically flexible interconnects having multiple materials according to representational embodiments.

FIG. 3A illustrates a cross-sectional view of a mechanically flexible interconnect according to various embodiments.

FIGS. 3B and 3C illustrate a number of top views corresponding to the cross-sectional view of FIG. 3A according to various embodiments.

FIG. 3D illustrates a cross-sectional view of another mechanically flexible interconnect according to various embodiments.

FIGS. 3E and 3F illustrate a number of top views corresponding to the cross-sectional view of FIG. 3D according to various embodiments.

FIG. 3G illustrates a cross-sectional view of another mechanically flexible interconnect according to various embodiments.

FIGS. 3H and 3I illustrate a number of top views corresponding to the cross-sectional view of FIG. 3G according to various embodiments.

FIGS. 4A-4F illustrate an example of a method to create mechanically flexible interconnects according to various embodiments.

FIGS. 5A and 5B illustrate cross-sectional views of integrated circuits incorporating mechanically flexible interconnects according to various embodiments.

FIG. 6 illustrates a cross-sectional view of a temporary testing interface incorporating mechanically flexible interconnects according to a representational embodiment.

FIG. 7 illustrates a cross-sectional view of an integrated circuit incorporating a bridge chip and mechanically flexible interconnects according to a representational embodiment.

FIGS. 8A-8D illustrate an example of a method to create a pogo pin structure according to a representational embodiment.

FIGS. 9A-9B illustrate an example of a method to create another pogo pin structure according to a representational embodiment.

FIG. 9C illustrates an example of another pogo pin structure according to a representational embodiment.

### DETAILED DESCRIPTION

Before the present disclosure is described in greater detail, it is to be understood that this disclosure is not limited to particular embodiments described, and as such may, of course, vary. It is also to be understood that the terminology used herein is for the purpose of describing particular embodiments only, and is not intended to be limiting, since the scope of the present disclosure will be limited only by the appended claims.

Where a range of values is provided, it is understood that each intervening value, to the tenth of the unit of the lower limit unless the context clearly dictates otherwise, between the upper and lower limit of that range and any other stated or intervening value in that stated range, is encompassed within the disclosure. The upper and lower limits of these smaller ranges may independently be included in the smaller ranges and are also encompassed within the disclosure, subject to any specifically excluded limit in the stated range. Where the stated range includes one or both of the limits, ranges excluding either or both of those included limits are also included in the disclosure.

Unless defined otherwise, all technical and scientific terms used herein have the same meaning as commonly understood by one of ordinary skill in the art to which this disclosure belongs. Although any methods and materials similar or equivalent to those described herein can also be used in the practice or testing of the present disclosure, the preferred methods and materials are now described.

As will be apparent to those of skill in the art upon reading this disclosure, each of the individual embodiments described and illustrated herein has discrete components and features which may be readily separated from or combined with the features of any of the other several embodiments without departing from the scope or spirit of the present disclosure. Any recited method can be carried out in the order of events recited or in any other order that is logically possible.

Embodiments of the present disclosure will employ, unless otherwise indicated, techniques of microelectronics, electrical engineering, computer engineering, material science, mechanical engineering, and the like, which are within the skill of the art.

The following examples are put forth so as to provide those of ordinary skill in the art with a complete disclosure and description of how to perform the methods and use the probes disclosed and claimed herein. Efforts have been made to ensure accuracy with respect to numbers (e.g., amounts, temperature, etc.), but some errors and deviations should be accounted for. Unless indicated otherwise, parts are parts by volume, temperature is in ° C., and pressure is at or near atmospheric. Standard temperature and pressure are defined as 20° C. and 1 atmosphere.

Before the embodiments of the present disclosure are described in detail, it is to be understood that, unless otherwise indicated, the present disclosure is not limited to particular materials, reagents, manufacturing processes, or the like, as such can vary. It is also to be understood that the terminology used herein is for purposes of describing particular embodiments only, and is not intended to be limiting. It is also possible in the present disclosure that steps can be executed in different sequences where this is logically possible.

It must be noted that, as used in the specification and the appended claims, the singular forms “a,” “an,” and “the” include plural referents unless the context clearly dictates otherwise. Thus, for example, reference to “a compound” includes a plurality of compounds. In this specification and in the claims that follow, reference will be made to a number of terms that shall be defined to have the following meanings unless a contrary intention is apparent.

Processes used in integrated circuit fabrication often place a premium on uniformity of features on a substrate. Interconnects for connecting integrated circuits are often made with uniform dimensions and materials so that all interconnects will have similar properties. In order to change the properties of features, such as interconnects, industry solutions focus on changing width while keeping uniform thickness. For example, in modern industry practice a metal layer can have uniform thickness. However, in the field of mechanically deformable interconnects, which have applications in packaging, sockets, wafer probing, connectors, and the like, varying the width alone can be insufficient to maintain a similar mechanical compliance. One example of this is when the distance between two chips, or any surfaces with electrical interface, has a large variance, requiring interconnects of different lengths in order to make contact with different areas on the chips. In this situation, varying the width of the interconnect alone may be insufficient to maintain similar compliance.

One type of interconnect is a mechanically flexible interconnect (MFI). Generally, the present disclosure relates to devices and systems incorporating multiple MFIs having multiple thicknesses and/or multiple materials on the same substrate, while maintaining similar compliance in each. As used herein, the term substrate can refer to substrates, chips, integrated circuits, testing interfaces, wafers, dies, chips, package substrates, flexible substrates, and the like.

Compliance is an important consideration in interconnect design. Compliance refers to how flexible a structure is. It is a measure of the deformation or deflection of an object when a certain force is applied. Compliance of a structure can be measured, for example, in meters per newton, inches per pound, or other appropriate measure. The reciprocal of compliance is stiffness, or the resistance to deformation offered by an object. An object can also have a rotational compliance, indicating the change in angle of the object when a moment is applied, which can be measured in radians per newton-meter, degrees per inch-pound, and the like.

A number of factors can affect compliance of an object, including material, geometry of the object, and other factors. Geometry of the object can affect its compliance in a number of ways. For example, a structure can deflect when a force is applied, and the deflection is related to the geometry of the structure. To best understand this, let us consider a simple uniform beam with a force applied at the top. One way to calculate deflection of such a beam is

$$δ = \frac{F \times {L}^{3}}{3 \times E \times I} \qquad ( 1 )$$

where F is the force applied, L is length, E is elastic modulus, and I is moment of inertia.

Generally, a structure of greater length has a greater compliance (will be more flexible), and will have an increased deflection when force is applied, and an object of lesser length will have a lesser compliance (will be more stiff).

Moment of inertia I, which appears in equation (1), can be calculated for a rectangular structure as

$$I = \frac{{T}^{3} \times W}{12} \qquad ( 2 )$$

Where T is thickness and W is width. Thus geometric factors such as Length, Thickness, and Width can each affect compliance, as well as deflection of a structure when a force is applied. While equations (1) and (2) can be used to illustrate one compliance calculation for a simple structure, an object's specific geometry, such as its shape, dimensions, and connection to other objects, for example, can further affect compliance. Complex or irregular geometries and configurations can have more complex compliance and deflection calculations.

The different lengths of the MFIs can affect compliance or stiffness, as compliance is a property related to structure or geometry of an object. As discussed above, compliance is proportional to length such that a longer object is more compliant. Thus, all other factors being equal (such as material, shape, and the like), MFIs of different lengths can have different compliance, longer MFIs being more compliant than shorter MFIs. While MFIs are often described in terms of length above, the size of an MFI can also be described by its height above the substrate upon which the MFI is formed. An MFI's height, then, can also affect compliance.

MFIs can be manufactured on a single substrate to have a different geometry, material composition, and/or pitch. An MFI can be used as a compliant electrical interconnection between substrates or chips. For example, an MFI can be designed to extend from one chip to make contact with a pad on another chip. The flexible or compliant quality of the MFI allows the MFI to make effective contact with the pad at a range of distances between chips without causing undue stress, allowing for variances such as when the chips are imperfectly or irregularly shaped. While the MFIs are at times referred to as electrical interconnections, an MFI can also be used as a compliant physical interconnection among other uses.

As previously discussed, two or more substrates can be interfaced or connected in an electronic system, or a substrate can be temporarily connected to an integrated circuit for testing. To illustrate, a testing interface comprising a substrate can have a number of probes (interconnects) extending from the bottom of a substrate. To electrically connect the testing interface to an integrated circuit, the probes can be pressed against an integrated circuit having contact pads on the top of the integrated circuit. Assuming that the substrate and the integrated circuit are each perfectly flat, and each probe is exactly the same length, then all of the probes will make contact with the contact pads concurrently. The forces resulting from the connection will be equally distributed on each probe of the testing interface, and the forces on the integrated circuit will also be evenly distributed at each contact pad.

However, if one of the probes is longer than the other probes, and the probes are very stiff (not compliant), then the long probe will make contact first, and stress on the testing interface and/or the integrated circuit can result if all probes are forced to make contact with all contact pads in this situation. This is merely one way to illustrate potential stresses that can occur when connecting two substrates. Similar stresses can result, for example, if any portion of the testing interface, the probes, the contact pads, or the integrated circuit is imperfectly formed, or has minor variances, for example in size, shape, placement, composition, and the like. Mechanically flexible interconnects can help alleviate stresses caused by such imperfections or variances. In the above illustration, if the longer probe is an MFI, then at least some of the stress can be alleviated as the compliance of the longer MFI probe will flex as it makes contact with the contact pad, decreasing the stress on the integrated circuit and the testing interface.

Additionally, in the above illustration, if each of the probes of the testing interface are MFIs, they can each flex when each MFI makes contact with each corresponding contact pad of the testing interface. This would alleviate some of the stress on the integrated circuit and the testing interface as they are pressed together, even if all of the MFIs are the same length. All of the MFIs can also have similar compliance. If some of the MFIs have different compliance than other MFIs, the integrated circuit and the testing interface can be unduly stressed.

Integrated circuits, package substrates, motherboard substrates, and the like, can have irregular shapes. For example, while the substrate and the integrated circuit in the above illustration are described as being generally flat, in other situations, each may instead not be flat, causing the distance between the substrate and the integrated circuit to vary. Further, a substrate may have pads on different levels (i.e., different planes, such that a set of pads is higher than the other set). This would require MFIs of different lengths in order to make proper contact.

In another example, the top of a substrate can be flat, but a chip might be affixed to the top of the substrate such that the top of the chip is higher than the top of the substrate. If contact pads on the top of the substrate and the top of the chip are to be tested by a single, flat testing interface, MFIs (probes) extending from the testing interface can have different lengths to accommodate the contact pads on the top of the substrate and the top of the chip concurrently. In such a situation, varying the width of the MFIs alone in order to give each MFI a similar compliance may be impractical or impossible.

Geometry of an MFI can affect its compliance such that an increase in the thickness of an MFI decreases the compliance of the MFI. This application discloses multiple MFIs incorporating different geometries, such as different shapes, thicknesses, widths, and multiple materials, that can be made at various pitches on the same substrate. The MFIs can be designed to have a similar compliance. MFIs utilized on a chip, substrate, and the like, can have similar compliance, which is a design characteristic that can be chosen or selected to fit a particular purpose. A first plurality of MFIs utilized together can have a first compliance for one purpose, while a second plurality of MFIs utilized together can have a second compliance for another purpose. In an embodiment, the compliance can be about 1 μm/mN to about 20 μm/mN.

The MFIs can be incorporated on one or both sides of a substrate embodying a wafer, die, chip, package substrate, flexible substrate, and the like. A substrate can be silicon, glass, ceramic, organic, flexible polymeric, or other material, and can be incorporated into an integrated circuit. A substrate can also have additional features including but not limited to bumps of various pitches and sizes, vias, optical vias, optical waveguides, and the like that are formed on the same substrate as the MFIs. For example, electrical or physical connections can be made with bumps of various pitches of about 10 μm to about 2,000 μm and can include a variety of solder compositions or alloys such as tin-based solder. Bumps can also include copper bonding, gold-to-gold thermo-compression bonding, polymer bonding, epoxy bonding, and the like. Conductive pillars, for example, copper pillars or columns, can also be utilized in bumps or alone.

A substrate can have a number of planes on a single side of the substrate. For example, a trench can be dug in the substrate, or the surface of a substrate can be otherwise removed creating more than one plane on a single side. MFIs on a plane or surface of the substrate can have differing lengths, heights, thicknesses and/or widths, as well as different shapes and/or geometries. For example, MFI heights from a surface can be about 5 μm to about 200 μm, thicknesses can be about 2 μm to about 15 μm, and widths can be about 1 μm to about 100 μm. Where substrates are stacked in a 3D integrated circuit, bumps can be integrated adjacent to MFIs in order to securely hold the structure together. A glue-like polymer or an epoxy can also be used locally in certain positions on the chips.

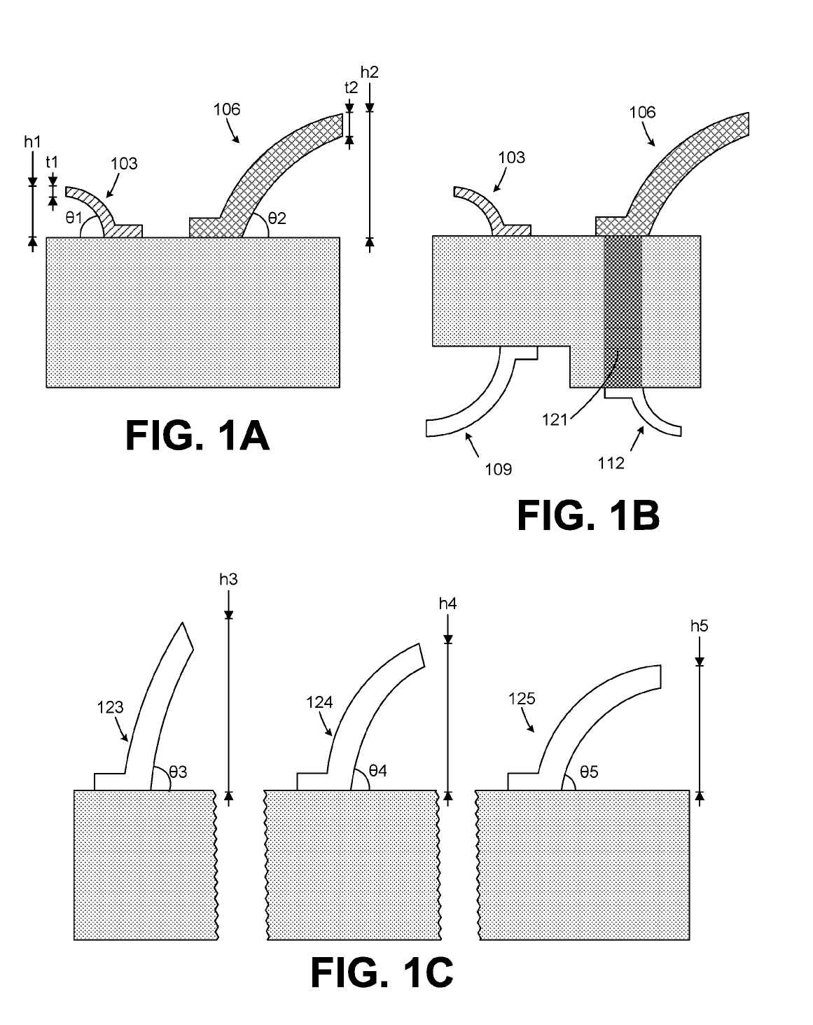

Turning to the figures, FIG. 1A illustrates a cross-sectional view of an MFI 103 and an MFI 106 on a top surface of a substrate, according to a representational embodiment. The MFI 103 has a thickness t1, a height h1, and an angle θ1. The MFI 106 has a thickness t2, a height h2, and an angle θ2. The thickness t2, height h2, and angle θ2 can be different from the thickness t1, height h1, and angle θ1, respectively. The different hatching of the MFI 103 and the MFI 106 is used to indicate that the materials used in the MFI 103 and the MFI 106 can be different. The different heights h1 and h2 allow the MFIs 103 and 106 to be utilized, for example, as an electrical connector to contact pads on a chip that has a non-planar (or a multi-planar) surface. Despite having different heights, the MFI 103 and the MFI 106 can have a similar compliance, as a result of their different thicknesses, different angles with respect to the substrate, and/or their different materials. This can minimize stress when making contact with a chip, die, wafer, and the like.

Referring to FIG. 1B, the MFI 103 and the MFI 106 are again shown on a top surface of a substrate. In FIG. 1B, however, additionally shows an MFI 109 and an MFI 112 extending from a bottom surface of the substrate. Thus FIG. 1B illustrates that MFIs can be formed on the top surface and the bottom surface of the substrate. Further, the bottom surface of the substrate has more than one plane, or is multi-planar. The MFI 109 extends from a first plane of the bottom surface, while the MFI 112 extends from a second plane of the bottom surface.

FIG. 1B illustrates how the different heights of the MFI 109 and the MFI 112 can be utilized on the multi-planar bottom surface of the substrate to make effective contact, for example, with a flat substrate. For clarity, no hatching is used in the MFI 109 and the MFI 112, but each of the MFIs 103, 106, 109, and 112 of FIG. 1B can have a different material composition and/or different thickness of materials. Among the various embodiments, the MFIs 109 and 112 can have a similar compliance to each other, and/or to the MFIs 103 and 106.

Next, referring to FIG. 1C, shown is an MFI 123, an MFI 124, and an MFI 125. Each of the MFIs 123, 124, and 125 are formed on a surface of a substrate. The MFI 123 has an angle θ3 and a height h3, the MFI 124 has an angle θ4 and a height h4, and the MFI 125 has an angle θ5 and a height h5. While each of the MFIs 123, 124, and 125 has a vertically curved geometry, each has a different geometry. For example, while each of the MFIs 123, 124, and 125 have a similar size and thickness, each can have a different geometry or shape. For example, each of the MFIs 123, 124, and 125 have a different angle (e.g., 5 to 89°) with respect to the substrate surface, resulting in each having a different height. The change in height for each of the MFIs 123, 124, and 125 could, for example, each be described as a different function of horizontal distance. The geometries of the MFIs 123, 124, and 125 affect the compliance of each. However, the MFIs 123, 124, and 125 can be made to have similar compliance, for example, by varying the material composition of each.

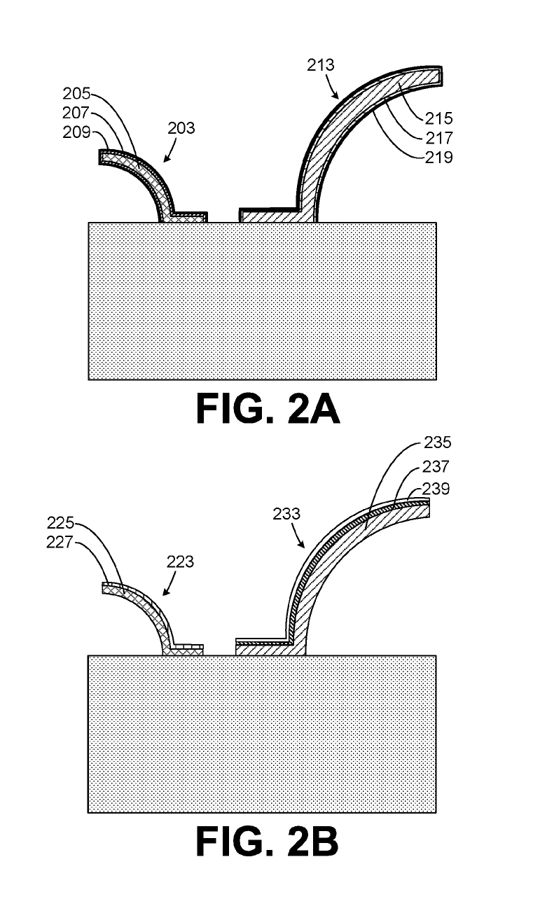

FIG. 2A illustrates a cross-sectional view of an MFI 203 and an MFI 213. The MFI 203 and the MFI 213 each have three layers. Although three layers are shown, 2 to 10 layers could be used based on the desired properties of the MFI. The MFI 203 is made of a core layer 205, a first outer layer 207, and a second outer layer 209. Each of the layers 205, 207, and 209 are different materials but in further embodiments they may be layers of the same material. The core layer 205 can, for example, be made by electroplating on a seed layer on the surface of a curved shape of photoresist. In one situation, the core layer 205 can be chosen to have a high electrical conductivity, such as copper, beryllium copper, and the like. In some examples, materials with high electrical conductivity may have a low yield strength and high compliance. In other embodiments, the core layer may not be selected for its conductivity, and may be selected for other properties.

The first outer layer 207 envelops the core layer 205. The first outer material 207 can be made by electroplating over the core layer 205 while nothing is under the core later 205 and can be chosen to have a higher yield strength, a lower compliance, or both. One example of a high yield strength material is NiW. In other embodiments, the first outer layer may not be selected for its conductivity, and may be selected for other properties.

The second outer layer 209 envelops the first outer material 207, and can be made via electroplating, passivation, and the like. The second outer material 209 can similarly be chosen for its properties. There may also be additional layers of additional materials on the MFI 203. Each layer in the MFI 203 can be made via electroplating, passivation, or other process, and each layer can have a different thickness. In some situations, the outermost layer of an MFI can be gold or other conductive, non-corrosive material. In other embodiments, the outermost layer may be selected for other properties. As used herein, a layer can be a few molecular layers to about 15 μm thick, and can completely or partially cover a surface, and can have an evenly or unevenly distributed thickness.

Much like the MFI 203, the MFI 213 is made of a core layer 215, a first outer layer 217, and a second outer layer 219. Each of the layers 215, 217, and 219 are different materials, but in other embodiments they may be layers of the same material. The core layer 215 of the MFI 213 is shown as having a different material and different thickness from the core layer 205 of the MFI 203. In other embodiments, they may have the same or different material and thickness. The first outer layer 217 envelops the core layer 215 of the MFI 213. The first outer layer 217 is shown as a different material from the first outer layer 207, but in other embodiments each can have the same or different material and thickness. The second outer layer 219 envelops the first outer layer 217. As shown, the second outer layer 219 is the same as the second outer layer 209, but in other embodiments each can have the same or different material and thickness. There may also be additional layers of additional materials on the MFI 213, each layer having its own thickness. This can be achieved, for example, by electroplating a layer on one MFI while the other MFI is protected, for example, by covering it with a layer of photoresist.

While each layer in the MFI 203 and the MFI 213 can have its own material, geometry, length, width, and thickness, the MFI 203 and the MFI 213 can be designed to have a similar compliance once fully formed. In this way, the MFIs can be customizable to fit the application local to their probing or interconnection location while minimizing stresses involved with interconnections as discussed. This enables fine-grain customization of the flexible interconnects on the same wafer, die, package substrate, or motherboard.

Moving to FIG. 2B, illustrated is a cross-sectional view of an MFI 223 and an MFI 233. The MFI 223 has two layers, while the MFI 233 has three layers. This illustrates that MFIs can be made with the same or different number of layers. The MFI 223 has a core layer 225, and an outer layer 227. The MFI 233 has a core layer 235, and a first outer layer 237, and a second outer layer 239. Each layer in the MFIs 223 and 233 has its own material and its own thickness.

In one example, the MFI 223 can be made by electroplating the core layer 225 on a seed layer on the surface of a curved shape of photoresist. The outer layer 227 can be made by electroplating on the core layer 225 while the photoresist remains under the core layer 225, completing the MFI 223.

The MFI 233 can be made using a similar process for the core layer 235 as the core layer 225, and a similar process for the outer layers. While not shown, each of the MFIs 223 and 233 can have a number of additional layers that envelop the MFIs 223 and 233. FIG. 2B illustrates that MFIs having multiple materials can be formed such that the materials are distributed in different ways. Each layer in the MFIs 223 and 233 of FIG. 2B is formed on top of the previous layer, whereas each layer of the MFIs 203 and 213 of FIG. 2A envelops the previous layer. MFIs can also have other distributions of materials.

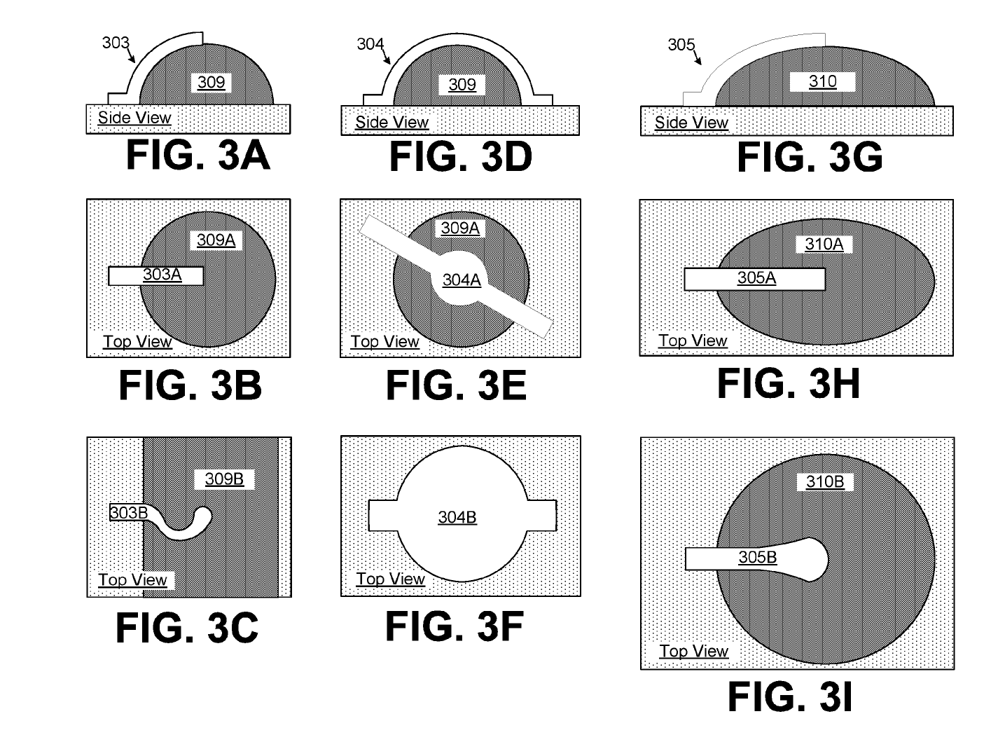

FIG. 3A illustrates a side view of an MFI 303 formed on photoresist 309. The photoresist 309 has a curved cross section. The MFI 303 has a vertically curved cross section corresponding to the photoresist 309. Such a form of photoresist can be formed in a number of ways such as reflowing a form of photoresist made by exposure and development, placing a dot of photoresist on the surface of a substrate, injection molding, surface wetting chemistries to control reflow, or other techniques.

FIG. 3B illustrates one example of a possible top view of the MFI 303 on the photoresist 309 of FIG. 3A. An MFI 303A having a rectangular top view is shown on photoresist 309A. The photoresist 309A has a circular top view. The photoresist here may be substantially in the form of a hemisphere on the surface of the substrate. However, it can also take on the form of a semi-oval shape, trapezoidal, semi-cylindrical, or others. Moreover, one can form one hemisphere photoresist pattern with one MFI and semi-oval photoresist pattern with a second MFI side by side. This will, again, enable someone to create MFIs with high degree of local customization on the same substrate.

FIG. 3C illustrates another example of a possible top view of the MFI 303 on the photoresist 309 of FIG. 3A. An MFI 303B having an irregular, curved, top view is shown on photoresist 309B. The photoresist 309B has a rectangular top view. The photoresist here may be substantially in the form of half of a cylinder on the surface of the substrate. Accordingly, more than one shape of photoresist can correspond to a similar side or cross-sectional view. Additionally, the different top views affect the geometry of the resulting MFIs and can result in differing compliance even when the cross sectional view of each MFI appears similar.

FIG. 3D illustrates a side view of an MFI 304 formed on the photoresist 309.

FIG. 3E illustrates one example of a possible top view of the MFI 304 on the photoresist 309 of FIG. 3D. An MFI 304A having a rectangular top view with a circular shape in the middle (the top) is shown on the photoresist 309A. The photoresist here may be substantially in the form of a hemisphere on the surface of the substrate, as in FIG. 3B. Accordingly, MFIs with different top views can be formed on the same photoresist shape.

FIG. 3F illustrates another example of a possible top view of the MFI 304 on the photoresist 309 of FIG. 3D. An MFI 304B is shown having a circular top view, with rectangular tabs on the left and right. The MFI 304B covers substantially all of the photoresist 309 (not shown), which is similar to the photoresist in FIGS. 3B and 3E.

FIG. 3G illustrates a side view of an MFI 305 formed on photoresist 310, which has a similar height to the photoresist 309, but is wider than the photoresist 309. The differences in the cross sections of the photoresist 309 and the photoresist 310 cause the MFI 305 to have a different vertically curved geometry than the MFI 303.

FIG. 3H illustrates one example of a possible top view of the MFI 305 on the photoresist 310 of FIG. 3G. An MFI 305A having a rectangular top view is shown on photoresist 310A. The photoresist 310A has an ovular top view.

FIG. 3I illustrates another example of a possible top view of the MFI 305 on the photoresist 310 of FIG. 3G. An MFI 305B having a rectangular top view that widens at the tip is shown on photoresist 310B. The photoresist 310B has a circular top view.

Further MFIs can be formed having a wide variety of geometries with different side views and top views. In some embodiments, an MFI can have a multi-pronged tip. Similarly, the photoresist upon which the MFIs can be formed can have a wide variety of side views and top views.

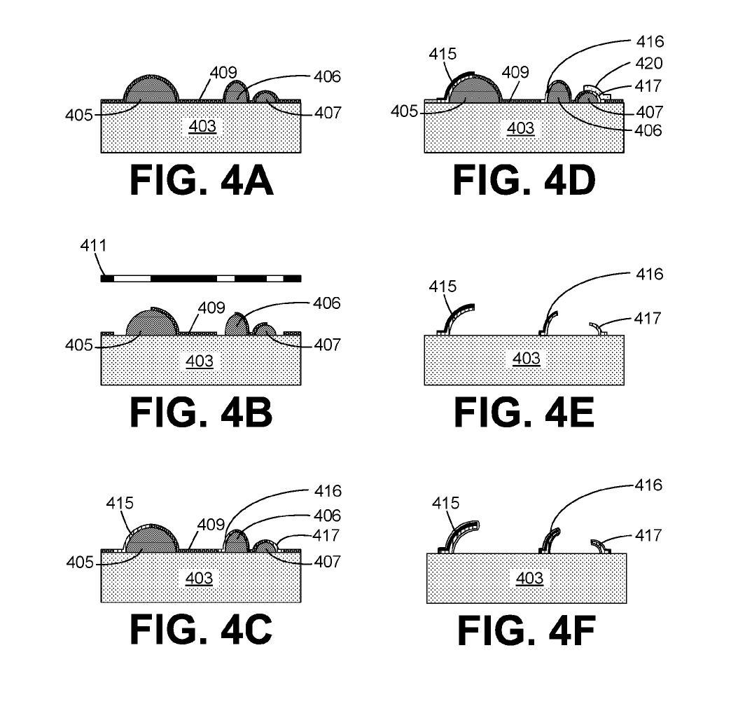

FIGS. 4A-4F illustrates an embodiment of making MFIs according to various embodiments. These figures illustrate a number of principles that can be used in a variety of ways to create MFIs.

FIG. 4A shows a cross-sectional view of a substrate 403. The substrate 403 has on its surface a photoresist mound 405, a photoresist mound 406, and a photoresist mound 407. In this example, the mound 405 is larger than the mound 406, which is larger than the mound 407. A coating of photoresist 409 covers the substrate 403 as well as the photoresist mounds 405, 406, and 407. The photoresist 409 can be applied, for example, as a spray coating or otherwise.

The photoresist mound 405 can be made in a number of ways. For example, a layer of photoresist can be formed on the substrate by spin coating. The spin coating can be exposed to a pattern of light and developed, leaving a shape of photoresist that can be reflowed to make the mound 405. Alternatively, the mound 405 can be formed by injection molding, stamping, 3D printing, or other techniques.

The photoresist mounds 406 and 407 can similarly be made in a number of ways. For example, mounds 406 and 407 can be formed, much like the mound 405, by exposing a spin coating to a pattern of light, developing, and reflowing the remaining shapes. In another example, a spin coated layer of photoresist can be formed on the substrate. The spin coating can be exposed to a first pattern of light and can be developed a first time, leaving a single shape of photoresist that can be reflowed to appear much like the mound 405. The reflowed shape can be exposed to a second pattern of light and can be developed a second time, leaving two smaller shapes. These smaller shapes can then be reflowed to make mounds 406 and 407. Alternatively, the mounds 406 and 407 can be formed by injection molding, stamping, 3D printing, or other techniques. The mounds 405, 406, and 407 can each be made using the same or different techniques or processes, for example the mound 405 may be made using an exposure, development, and reflow method while the mound 406 is 3D printed, and the mound 407 is injection molded, and the like.

FIG. 4B shows the substrate 403, the mounds 405, 406, and 407, and the photoresist 409 as also depicted in FIG. 4A. In FIG. 4B, the photoresist 409 has been exposed to light using a mask 411, and developed to create a pattern in the photoresist 409.

FIG. 4C shows the substrate 403, the mounds 405, 406, and 407, and the patterned photoresist 409 as depicted in FIG. 4B. MFIs 415, 416, and 417 are formed on the mounds 405, 416, and 417, respectively. In this example, the MFIs 415, 416, and 417 are metalized concurrently, and will have a similar thickness and material. In other examples, metallization for each of the MFIs 415, 416, and 417 can be performed individually.

The MFIs 415, 416, and 417 can be formed by electroplating or other metallization techniques. Metallization may require a seed layer (not shown) to facilitate electroplating. In this example, the seed layer can be formed on the surface of the substrate 403, the mounds 405, 406, and 407 before the photoresist 409 is applied. When the photoresist 409 is patterned using the mask 411, the seed layer can be exposed for metallization. A first metallization for a first duration forms the MFI 415 and the MFIs 417.

FIG. 4D shows the mounds 405, 406, and 407, the patterned photoresist 409, as well as the MFIs 415, 416, and 417, as in FIG. 4C. Photoresist 420 is shown covering the MFI 417. The photoresist 420 can be applied, for example, as a spray coating or other appropriate manner. Once the photoresist 420 is applied, a second metallization for a second duration can be applied on the MFIs 415 and 416 while the MFI 417 is not exposed and metallized. The second metallization of the MFIs 415 and 416 for the second duration can be the same material or a different material than the first duration. Because the photoresist mound 405 remains under the MFI 415, the second metallization results in the second layer being formed generally on the top of the MFIs 415 and 416. The MFI 417 are unaffected.

FIG. 4E shows the MFIs 415, 416, and 417 on the substrate 403, with all photoresist layers removed, for example, by development.

FIG. 4F shows the result of a third metallization for a third duration after all photoresist layers are removed. The MFIs 415 and 416 now have a third layer, and the MFI 417 now has a second layer. Since the third metallization occurs after all photoresist layers are removed, the resulting layer on each MFI fully envelops each MFI.

MFIs can also be transferred from one substrate to another substrate. For example, a solder ball can be placed at the tip of the MFI 415. Another substrate can, for example, be lowered from above and connected to the solder ball on the tip of the MFI 415. Once the MFI 415 is attached to the other substrate, the MFI 415 can be transferred to the other substrate by detaching the MFI 415 from the substrate 403.

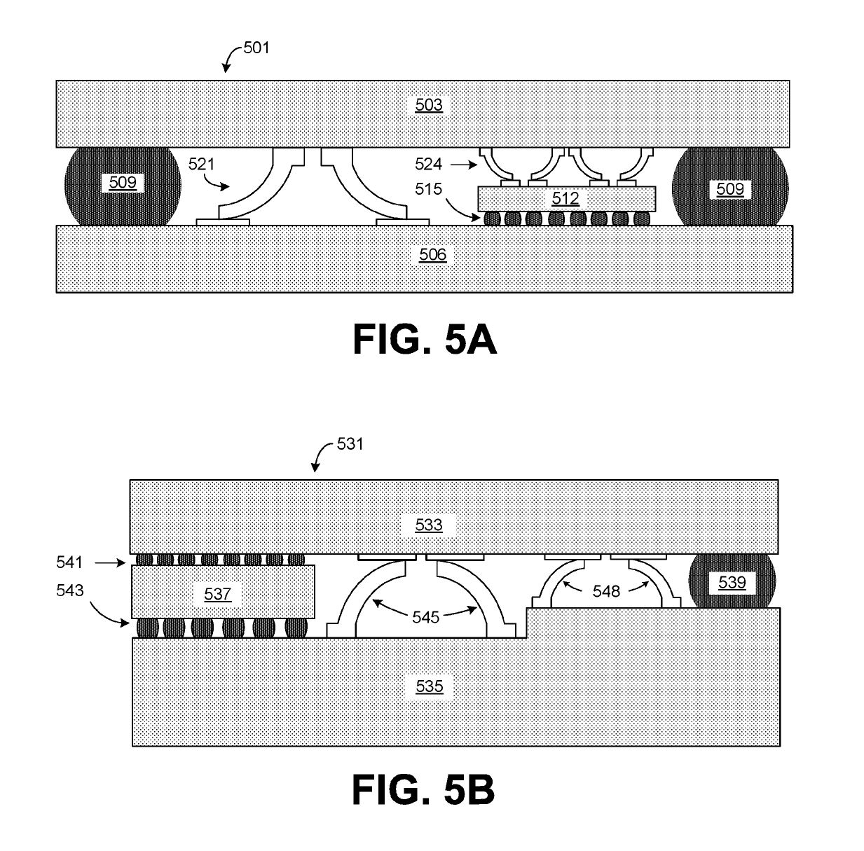

FIG. 5A illustrates a cross-sectional view of an integrated circuit 501 according to one embodiment. The integrated circuit 501 has a substrate 503 physically connected to a substrate 506 using large bumps 509. A chip 512 is electrically connected to the substrate 506 using small pitch bumps 515. MFIs 521 extend from the substrate 503 to electrically connect the substrate 503 to contact pads on the substrate 506. MFIs 524 extend from the substrate 503 to electrically connect the substrate 503 to contact pads on the chip 512.

Since the chip 512 is on top of the substrate 506, the distance between the substrate 503 and the substrate 506 is greater than the distance between the substrate 503 and the chip 512. As a result, the MFIs 521 must be longer than the MFIs 524 in order to make even contact. As discussed earlier, however, the MFIs 521 and the MFIs 524 can have a similar compliance in order to reduce the stress of interconnection and to enable substantially equivalent contacting force. To this end, the MFIs 521 and the MFIs 524 can have a different thickness and/or comprise a different material or materials.

The large bumps 509 are located at the edges of the integrated circuit 501 and provide a solid physical connection that keeps the MFIs 521 and the MFIs 524 of the substrate 503 connected to contact pads on the substrate 506 and the chip 512, respectively. Note that adhesive polymeric materials can also be used.

FIG. 5B shows a cross-sectional view of an integrated circuit 531 according to a representational embodiment. The integrated circuit 531 has a substrate 533, a substrate 535, and a chip 537. The substrate 533 is physically connected to the substrate 535 on one side using a large bump 539. On the other side, the substrate 533 is physically and electrically connected to the chip 537 using bumps 541. The chip 537 is in turn physically and electrically connected to the substrate 535 using bumps 543. The bumps 541 and 543 each have different pitch and size. Note wire bonds might be used to replace one of the bump layers on chip 537.

MFIs 545 and MFIs 548 extend from the substrate 535 to connect to contact pads on the substrate 533. The substrate 535 has two planes, so the MFIs 545 must be long than the MFIs 548 in order to make even contact to the contact pads of the substrate 533. The MFIs 545 and the MFIs 548 can have a similar compliance in order to reduce the stress of interconnection and can have a different thickness and/or comprise different material or materials. A solid physical connection between the substrate 533 and the substrate 535 is made using a combination of the large bump 539 and the connection through the chip 537 (and the bumps 541 and 543).

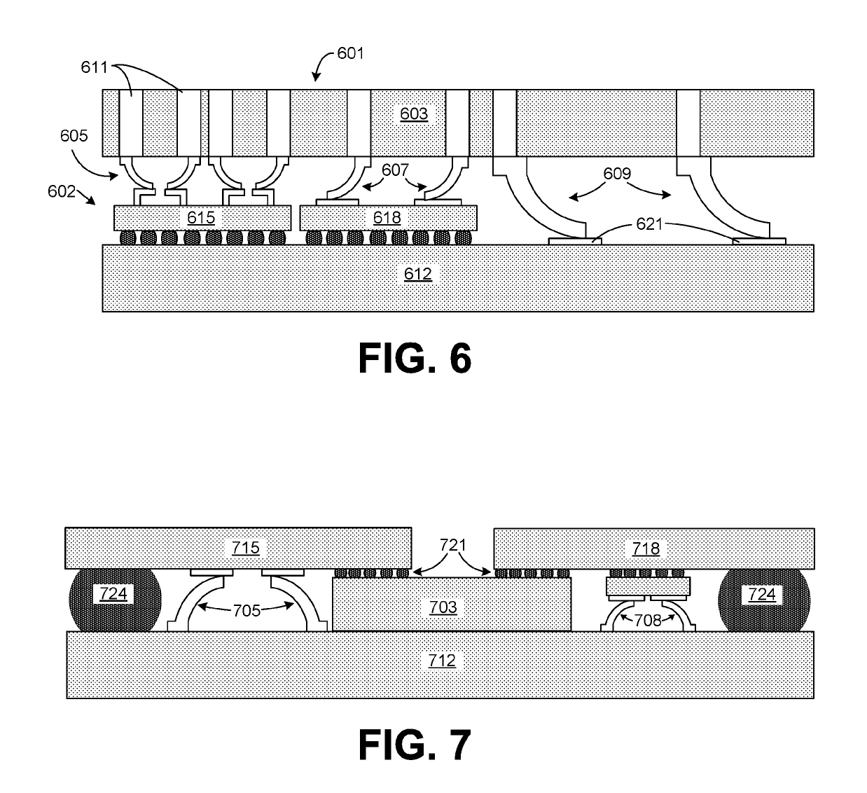

FIG. 6 illustrates a cross-sectional view of a temporary testing interface 601 according to a representational embodiment. The temporary testing interface 601 can be used to test an integrated circuit 602. To this end, the temporary testing interface 601 has a substrate 603, and a number of MFIs 605, 607, and 609 extending from a bottom surface of the substrate 603. Vias 611 can be used to make connection to other equipment or chips through the temporary testing interface 601. The temporary testing interface 601 can also incorporate additional MFIs (not shown) on its top surface, for example, connected to the vias 611 or contact pads (not shown) on its top surface.

The integrated circuit 602 has a substrate 612 with a number of contact pads 621 on a top surface of the substrate 612. A MEMS chip 615 and an ASIC chip 618 are also on the top surface of the substrate 612. The MFIs 605, 607, and 609 each have different lengths or heights measured from the substrate, to accommodate the MEMS chip 615, the ASIC chip 618, and the contact pads 621 of the integrated circuit 602. The MFIs 605, 607, and 609 can also have different thicknesses and/or comprise a different material or materials so each has an appropriate compliance for connection to the MEMS chip 615, the ASIC chip 618, and the contact pads 621 of the integrated circuit 602, respectively.

The temporary testing interface 601 may not be permanently connected to the integrated circuit 602. Instead, the temporary testing interface 601 can be held in place temporarily, or can, for example, be raised/lowered into a position to make connection between the MFIs 605, 607, and 609 and the integrated circuit 602 for testing or other purposes.

FIG. 7 illustrates a cross-sectional view of a circuit incorporating a bridge chip 703 and MFIs 705 and 708, according to a representational embodiment. The bridge chip 703 is attached to a substrate 712, and provides physical and electrical connections between a chip 715 and a chip 718. In this case, the chip 718 is an integrated circuit with another chip attached to its bottom surface. The bridge chip 703 further provides a physical and electrical connection from the substrate 712 to the chip 715 and the chip 718, respectively.

The MFIs 705 extend from the substrate 712 to make contact with the chip 715. The MFIs 708 extend from the substrate 712 to make contact with the chip 718. The MFIs 705 and the MFIs 708 can have a similar compliance in order to reduce the stress of interconnection and can have a different thickness and/or comprise different material or materials. The bridge chip can use fine-pitch bumps 721 for electrical and physical connections. The fine-pitch bumps 721 can be used in a variety of situations such as when the required pitch, or the number of required connections, is impractical for MFIs. MFIs can still be utilized for other connections, however. A solid physical connection between the substrate 712 and each of the chip 715 and the chip 718 is made using a combination of large bumps 724 and the bridge chip 703.

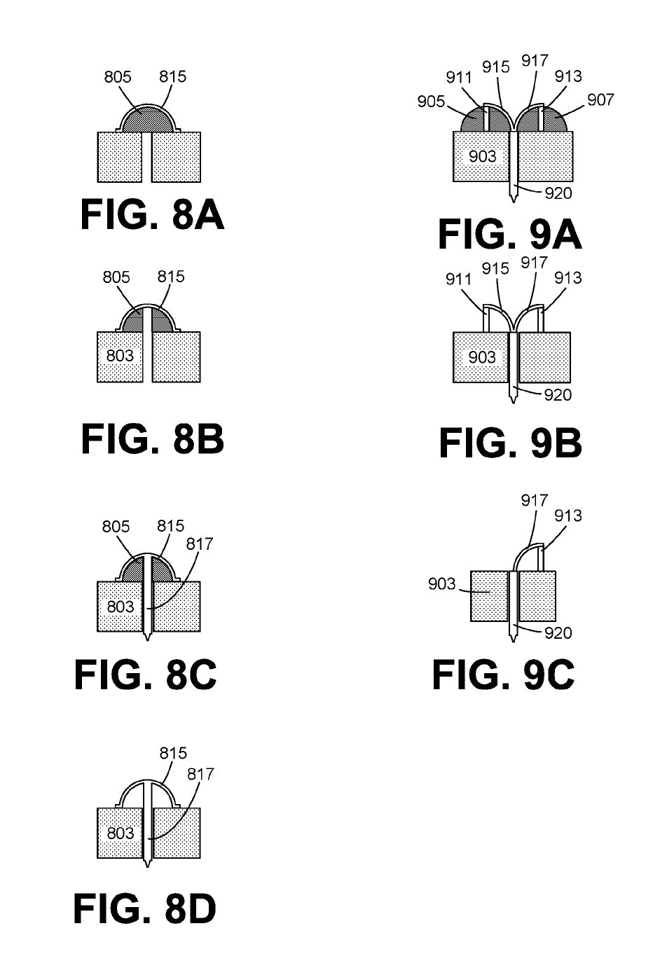

FIGS. 8A-8D show one way to create a pogo pin structure using MFIs according to various embodiments. Many of the methods discussed above can also be used in conjunction with FIGS. 8A-8D. FIG. 8A shows a cross-sectional view of a substrate 803 with a photoresist mound 805 formed on the surface of the substrate 803. The photoresist mound 805 can be formed in any of the previously discussed methods. An MFI 815 is formed on the surface of the mound 805. There is a via through the substrate, under the mound 805. In some embodiments, a layer of silicon dioxide or other material between the mound 805 and the substrate 803 can be utilized to aid the support of the mound 805 while forming the mound 805. In other embodiments, no such layer is used.

In FIG. 8B, the photoresist mound 805 is exposed to light from below and developed, leaving a hole in the mound 805. The substrate can act as a mask during exposure. In FIG. 8C, a pogo pin 817 is on the bottom surface of the MFI 815. In some embodiments, the pogo pin 817 can be pre-formed and attached from below. In other embodiments, a seed layer can be formed on the surface of the MFI 815 and metallization can be utilized to form the pogo pin 817. In some embodiments, a removable liner can be on the wall of the via through the substrate 803. The removable liner can help separate the pogo pin 817 from the wall of the via through the substrate 803 during formation or attachment, and be removed thereafter.

FIG. 8D shows the MFI 815 and the pogo pin structure 817 with the photoresist 805 removed, for example, by development. The MFI 815 can act as a spring, allowing the pogo pin 817 to move, and allowing for compliant connections using the pogo pin 817. The MFI 815 can also be used as an electrical connection in conjunction with the pogo pin 817. While the pogo pin 817 is shown with a sharp tip, in other embodiments, the tip of the pogo pin 817 can also be round, flat, or have a more complex shape or a multi-tipped shape. While the pogo pin 817 is shown protruding from the substrate, in other embodiments the pogo pin 817 can be within the substrate until a force is applied from above in order for the pogo pin 817 to make contact with another substrate.

FIG. 9A-9B shows a way to make another pogo pin structure according to various embodiments. Many of the methods discussed above can also be used in conjunction with FIGS. 9A-9B. In FIG. 9A, a substrate 903 is shown with photoresist mounds 905 and 907 formed on the surface of the substrate 903. The photoresist mounds 905 and 907 can be formed utilizing any of the previously discussed methods. A support 911 is shown in the mound 905 and a support 913 is shown in the mound 907. An MFI 915 is formed on the top of the mound 905, and an MFI 917 is formed on the top of the mound 907. The MFIs 915 and 917 can be formed in any of the previously discussed methods. A pogo pin 920 is connected to the MFIs 915 and 917, and can be connected or formed in any of the ways discussed above for the pogo pin 817.

In some embodiments, the supports 911 and 913 can be connected to the substrate 903 before the photoresist mounds 905 and 907 are formed, and the MFIs 915 and 917 can be formed on the surface of the photoresist mounds 905 and 907, respectively, thereafter. In other embodiments, the supports 911 and 913 can be formed, for example, by masking, exposing, and developing those areas of the photoresist 905, and 907, forming a seed layer and performing metallization. In some embodiments, the metallization of the supports 911 and 913 can be performed before the MFIs 915 and 917 are formed. In further embodiments, the supports 911 and 913 can be formed concurrently with the MFIs 915 and 917. The MFIs 915 and 917 can act as a spring, allowing the pogo pin 920 to move, and allowing for compliant connections using the pogo pin 920.

FIG. 9C shows another pogo pin structure according to various embodiments. In FIG. 9C, the pogo pin 920 is attached to the MFI 917, which is connected to the support 913. Compliance of pogo pins such as the pogo pin 817 and the pogo pin 920 can be affected by the MFI or MFIs to which each pogo pin is attached. Thus each pogo pin structure can be designed to have a contacting force that is similar to other pogo pin structures on a substrate, chip, testing interface, etc. A pogo pin structure can also be design to have a contacting force that is similar to that of an MFI or MFIs being utilized on the substrate, chip, testing interface, etc. While the discussion above may refer to pogo pins and MFIs as discrete components, a structure comprising a pogo pin and an MFI can itself be referred to as an MFI.

It should be noted that ratios, concentrations, amounts, dimensions, and other numerical data may be expressed herein in a range format. It is to be understood that such a range format is used for convenience and brevity, and thus, should be interpreted in a flexible manner to include not only the numerical values explicitly recited as the limits of the range, but also to include all the individual numerical values or sub-ranges encompassed within that range as if each numerical value and sub-range is explicitly recited. To illustrate, a concentration range of “about 0.1% to about 5%” should be interpreted to include not only the explicitly recited concentration of about 0.1 wt % to about 5 wt %, but also include individual concentrations (e.g., 1%, 2%, 3%, and 4%) and the sub-ranges (e.g., 0.5%, 1.1%, 2.2%, 3.3%, and 4.4%) within the indicated range. In an embodiment, the term “about” can include traditional rounding according to significant figures of the numerical value. In addition, the phrase “about ‘x’ to ‘y’” includes “about ‘x’ to about ‘y’”.

As used herein, the terms “similar compliance” and “substantially equivalent compliance” can refer to compliance that differs about 30% or less, about 25% or less, about 20% or less, about 15% or less, about 10% or less, or about 5% or less. As used herein, the terms “similar contacting force” and “substantially equivalent contacting force” can refer to contacting force that differs about 30% or less, about 25% or less, about 20% or less, about 15% or less, about 10% or less, or about 5% or less. The term “or less” can extend to 0 or to 0.01.

It should be emphasized that the above-described embodiments of the present disclosure are merely possible examples of implementations, and are set forth only for a clear understanding of the principles of the disclosure. Many variations and modifications may be made to the above-described embodiments of the disclosure without departing substantially from the spirit and principles of the disclosure. All such modifications and variations are intended to be included herein within the scope of this disclosure.

1-40. (canceled)

41. A substrate, comprising:
a first mechanically flexible interconnect having a first thickness;
a second mechanically flexible interconnect having a second thickness; and
wherein the first thickness and the second thickness are different, wherein the first mechanically flexible interconnect and the second mechanically flexible interconnect have a substantially equivalent compliance.

42. The substrate of claim 41, wherein the first mechanically flexible interconnect has a first substrate end and a first contact end, wherein the first substrate end connects with the substrate and the first contact end extends from the substrate a first distance, wherein the second mechanically flexible interconnect has a second substrate end and a second contact end, wherein the second substrate end connects with the substrate and the second contact end extends from the substrate a second distance, wherein the first distance and the second distance are different.

43. The substrate of claim 41, wherein at least one of the first mechanically flexible interconnect and the second mechanically flexible interconnect is vertically curved.

44. The substrate of claim 41, wherein the first mechanically flexible interconnect comprises a first geometry, and the second mechanically flexible interconnect comprises a second geometry, wherein the first geometry and the second geometry are different.

45. The substrate of claim 41, wherein the first mechanically flexible interconnect comprises a first material, and the second mechanically flexible interconnect comprises a second material, wherein the first material and the second material are different.

46. The substrate of claim 41, wherein the first mechanically flexible interconnect comprises a first core material and a first outer material, and the second mechanically flexible interconnect comprises a second core material and a second outer material.

47. The substrate of claim 41, wherein the first mechanically flexible interconnect and the second mechanically flexible interconnect are on a first side of the substrate, and a third mechanically flexible interconnect is on a second side of the substrate.

48. The substrate of claim 41, wherein the first mechanically flexible interconnect and the second mechanically flexible interconnect are on a first plane of the substrate, and a fourth mechanically flexible interconnect is on a second plane of the substrate.

49. The substrate of claim 41, further comprising a first plurality of bumps having a first pitch and a second plurality of bumps having a second pitch, wherein the first pitch and the second pitch are different.

50. The substrate of claim 41, wherein the first mechanically flexible interconnect is one of a first plurality of mechanically flexible interconnects having a first pitch, wherein the second mechanically flexible interconnect is one of a second plurality of mechanically flexible interconnects having a second pitch, and wherein the first pitch and the second pitch are different.

51. The substrate of claim 41, wherein the first mechanically flexible interconnect further comprises a pogo pin.

52. A bridge chip for connecting a plurality of chips, the bridge chip being configured to:
connect a first side of the bridge chip to a first chip via a first plurality of bumps;
connect the first side of the bridge chip to a second chip via a second plurality of bumps;
connect a second side of the bridge chip to a substrate; and
wherein the first chip is connected to the substrate via a first mechanically flexible interconnect, the second chip is connected to the substrate via a second mechanically flexible interconnect, and wherein the first mechanically flexible interconnect and the second mechanically flexible interconnect have a similar compliance.

53. The bridge chip of claim 52, wherein at least one bump makes a physical connection between the substrate and at least one of the first chip or the second chip.

54. The bridge chip of claim 52, wherein the first mechanically flexible interconnect has a first thickness and the second mechanically flexible interconnect has a second thickness, wherein the first thickness and the second thickness are different.

55. The bridge chip of claim 52, wherein first mechanically flexible interconnect has a first material composition and the second mechanically flexible interconnect has a second material composition, wherein the first material composition and the second material composition are different.

56. A method, comprising:
moving a testing interface into a testing position, wherein the testing interface comprises a first mechanically flexible interconnect and a second mechanically flexible interconnect, each of the first mechanically flexible interconnect and the second mechanically flexible interconnect having a similar compliance;
contacting the first mechanically flexible interconnect with a first portion of a circuit;
contacting the second mechanically flexible interconnect with a second portion of the circuit; and
testing the first portion of the circuit and the second portion of the circuit.

57. The method of claim 56, wherein the first portion of the circuit is in a first substrate and the second portion of the circuit is in a second substrate, wherein the first substrate is connected to the second substrate via at least one bump.

58. The method of claim 56, wherein the first mechanically flexible interconnect has a first thickness and the second mechanically flexible interconnect has a second thickness, wherein the first thickness and the second thickness are different.

59. The method of claim 56, wherein the first mechanically flexible interconnect has a first material composition and the second mechanically flexible interconnect has a second material composition, wherein the first material composition and the second material composition are different.

60. The method of claim 56, wherein at least one of the first mechanically flexible interconnect and the second mechanically flexible interconnect comprises a pogo pin.
